(19) United States
(12) Patent Application Publication
(10) Pub. No.: US 2009/0115518 A1
(43) Pub. Date: May 7, 2009

(54) DIFFERENTIAL AMPLIFIER WITH INPUT STAGE INVERTING COMMON-MODE SIGNALS

(75) Inventor: Adrianus J. M. Van Tuijl, Eindhoven (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/294,221

(22) PCT Filed: Mar. 21, 2007
(86) PCT No.: PCT/IB07/50993

§ 371 Date: Sep. 23, 2008

(30) Foreign Application Priority Data
Mar. 23, 2006 (EP) 06300271.1
Mar. 21, 2007 (IB) PCT/IB2007/050993

(51) Int. Cl. H03F 3/45

(52) U.S. Cl. 330/253; 330/257; 330/258

(57) ABSTRACT

To eliminate common-mode components in differential input signals without the necessity of introducing a transformer and a special feedback loop for eliminating common-mode components, a differential amplifier (1) comprises a first input stage (11) for receiving differential input signals comprising common-mode signals and for outputting first differential intermediate signals, a second input stage (12) for inverting the common-mode signals and for combining inverted common-mode signals and the first differential intermediate signals into second differential intermediate signals, and an output stage (13) for receiving the second differential intermediate signals and for outputting differential output signals. The first input stage (11) comprises a folded cascode stage with first and second transistors (31,32), the second input stage (12) comprises a mirror stage with third, fourth, fifth, sixth and seventh transistors (33,34,35,36,37), and the output stage (13) comprises a common main electrode stage with tenth and eleventh transistors (40,41).

### FIELD OF THE INVENTION

The invention relates to a differential amplifier, a device comprising a differential amplifier, a method of differentially amplifying differential signals, and a computer program product for performing the steps of the method.

Examples of such a device are television receivers as well as other consumer and non-consumer products, and circuits such as converters and tuners to be used in consumer and/or non-consumer products.

### BACKGROUND OF THE INVENTION

A prior-art device is known from U.S. Pat. No. 6,897,726, which discloses a differential circuit for an amplifier circuit. Such a known differential amplifier may comprise a basic feedback loop that provides a negative feedback from the output to the input for the differential input signals. If these differential input signals comprise common-mode signals (common-mode components), the basic feedback loop may provide, at least for certain common-mode signals, a positive feedback from the output to the input. This positive feedback may result in distortion because signals in the differential amplifier are clamped and/or may result in the differential amplifier starting to oscillate.

A first prior-art solution seeks to avoid distortion and/or oscillation in that the common-mode signals in the differential input signals are blocked by using a transformer. Such a transformer usually has an insufficient bandwidth.

In a second prior-art solution, an additional feedback loop is introduced, which provides only an additional negative feedback for the common-mode signals from the output to the input, which feedback is equal to or larger than the possible positive feedback from the output to the input for the common-mode signals. Such an additional feedback loop must have a bandwidth which is equal to or larger than the bandwidth of the basic feedback loop, which is often difficult to realize and makes the differential amplifier complex and expensive.

The known device has a drawback, inter alia, because distortion and/or oscillation, which result from the basic feedback loop when providing a positive feedback for at least certain common-mode signals, can only be avoided by reducing the bandwidth and/or increasing the complexity and costs to a relatively large extent.

### SUMMARY OF THE INVENTION

It is, inter alia, preferred to provide a differential amplifier which can handle differential input signals comprising common-mode signals without the necessity of introducing a feedback loop for common-mode stability.

It is, inter alia, a further object of the invention to provide a device comprising a differential amplifier, a method of differentially amplifying differential signals and a computer program product for performing the steps of the method, which can handle differential input signals comprising common-mode signals without the necessity of introducing a feedback loop for common-mode stability.

The differential amplifier according to the invention comprises:

a first input stage for receiving a differential input signal comprising a common-mode signal and for outputting a first differential intermediate signal,

a second input stage for inverting the common-mode signal and for combining an inverted common-mode signal and the first differential intermediate signal into a second differential intermediate signal, and

an output stage for receiving the second differential intermediate signal and for outputting a differential output signal.

The first (prior-art) input stage processes the differential input signals comprising the common-mode signals and, in response, generates the first differential intermediate signals. By introducing the second input stage in addition to the first (prior-art) input stage, which second input stage processes only the common-mode signals by inverting them and then combines these inverted common-mode signals and the first differential intermediate signals into the second differential intermediate signals, the detrimental common-mode signals are removed in the second input stage at least to a large extent. The second differential intermediate signals that are supplied from the second input stage to the output stage comprise reduced common-mode signals or even no common-mode signals at all. Therefore, it is no longer necessary to introduce a feedback loop from the differential output to the differential input solely for the purpose of ensuring common-mode stability. As a result, the differential amplifier according to the invention can handle differential input signals comprising common-mode signals without the necessity of introducing a feedback loop for common-mode stability.

It is a further advantage of the differential amplifier according to the invention that the second input stage removes the detrimental common-mode signals at least to a large extent before they reach the output stage, independently of the presence or absence of a basic feedback loop from the differential output to the differential input.

An embodiment of the differential amplifier according to the invention is characterized in that the first input stage comprises a folded cascode stage, the second input stage comprises a mirror stage and the output stage comprises a common main electrode stage. Other types of stages are not to be excluded.

An embodiment of the differential amplifier according to the invention is characterized in that the first input stage comprises first and second transistors having control electrodes which constitute differential inputs, said first and second transistors further having first main electrodes coupled to each other. The first differential intermediate signal is supplied via second main electrodes of the first and second transistors.

An embodiment of the differential amplifier according to the invention is characterized in that the second input stage comprises third and fourth transistors having control electrodes coupled to the control electrodes of the first and second transistors, respectively, said third and fourth transistors further having second main electrodes coupled to each other. The common-mode signal is supplied via the second main electrodes of the third and fourth transistors.

An embodiment of the differential amplifier according to the invention is characterized in that the first main electrodes of the first and second transistors are further coupled to a first reference terminal via a first current source, and the first main electrodes of the third and fourth transistors are coupled to each other and to the first reference terminal via a second current source. In this case, the first and second input stages have individual current sources that are coupled to the first reference terminal such as, for example, a positive voltage supply. Separate current sources improve the noise behavior of the differential amplifier.

An embodiment of the differential amplifier according to the invention is characterized in that the first main electrodes of the first and second transistors are further coupled to first main electrodes of the third and fourth transistors as well as to a first reference terminal via a first current source. In this case, the first and second input stages have a common current source that is coupled to the first reference terminal such as, for example, a positive voltage supply. A common current source reduces the number of components in the differential amplifier.

An embodiment of the differential amplifier according to the invention is characterized in that the second input stage further comprises fifth, sixth and seventh transistors having control electrodes coupled to each other, said fifth, sixth and seventh transistors further having first main electrodes coupled to each other and to a second reference terminal, while second main electrodes of the fifth and seventh transistor are coupled to second main electrodes of the first and second transistors, respectively, and a second main electrode of the sixth transistor is coupled to the second main electrodes of the third and fourth transistors and to the control electrode of the sixth transistor. The third and fourth transistors filter the common-mode signal from the differential input signal, and the fifth, sixth and seventh transistors invert this common-mode signal and combine the inverted common-mode signal and the first intermediate signal. The second reference terminal corresponds to, for example, ground.

An embodiment of the differential amplifier according to the invention is characterized in that it further comprises eighth and ninth transistors having control electrodes coupled to each other, said eighth and ninth transistors further having first main electrodes coupled to the second electrodes of the first and second transistors, respectively. The eighth and ninth transistors couple the second input stage and the output stage and may form part of either the second input stage or the output stage. The eighth and ninth transistors receive the second differential intermediate signals from the second input stage and supply them to the output stage.

An embodiment of the differential amplifier according to the invention is characterized in that the first main electrodes of the eighth and ninth transistors are further coupled to the second reference terminal via third and fourth current sources, respectively. These third and fourth current sources preclude the necessity of properly dimensioning the fifth and seventh transistors.

An embodiment of the differential amplifier according to the invention is characterized in that the output stage comprises tenth and eleventh transistors having control electrodes coupled to the second main electrodes of the eighth and ninth transistors, respectively, said tenth and eleventh transistors further having first main electrodes coupled to the second reference terminal as well as second main electrodes which constitute differential outputs and are coupled to a first reference terminal via fifth and sixth current sources, respectively, the control electrodes of said tenth and eleventh transistors being further coupled to the first reference terminal via seventh and eighth current sources, respectively, as well as to the second main electrodes of the tenth and eleventh transistors via respective circuits, said respective circuits having serial couplings each comprising a resistor and a capacitor. These serial couplings stabilize the differential amplifier.

Embodiments of the device, the method and the computer program product according to the invention correspond to the embodiments of the differential amplifier according to the invention.

The invention is based on the recognition that, inter alia, a transformer at the differential input of the differential amplifier and/or double feedback loops in the differential amplifier are to be avoided, and on the fundamental idea that, inter alia, a second input stage is to be introduced in the differential amplifier, which second input stage inverts a common-mode signal of a differential input signal and combines an inverted common-mode signal and a first differential intermediate signal originating from a first input stage into a second differential intermediate signal intended for an output stage.

The invention solves the problem in that it provides a differential amplifier which can handle differential input signals comprising common-mode signals without the necessity of introducing a feedback loop for common-mode stability. It is an advantage of the differential amplifier according to the invention that the second input stage removes the detrimental common-mode signals at least to a large extent before they reach the output stage, independently of the presence or absence of a basic feedback loop from the differential output to the differential input.

These and other aspects of the invention are apparent from and will be elucidated with reference to the embodiments described hereinafter.

### BRIEF DESCRIPTION OF THE DRAWINGS

In the drawings:

FIG. 1 shows diagrammatically a differential amplifier according to the invention,

FIG. 2 shows diagrammatically a device according to the invention comprising a differential amplifier according to the invention,

FIG. 3 shows diagrammatically a first embodiment of a differential amplifier according to the invention,

FIG. 4 shows diagrammatically a second embodiment of a differential amplifier according to the invention, and

FIG. 5 shows diagrammatically a third embodiment of a differential amplifier according to the invention.

### DESCRIPTION OF EMBODIMENTS

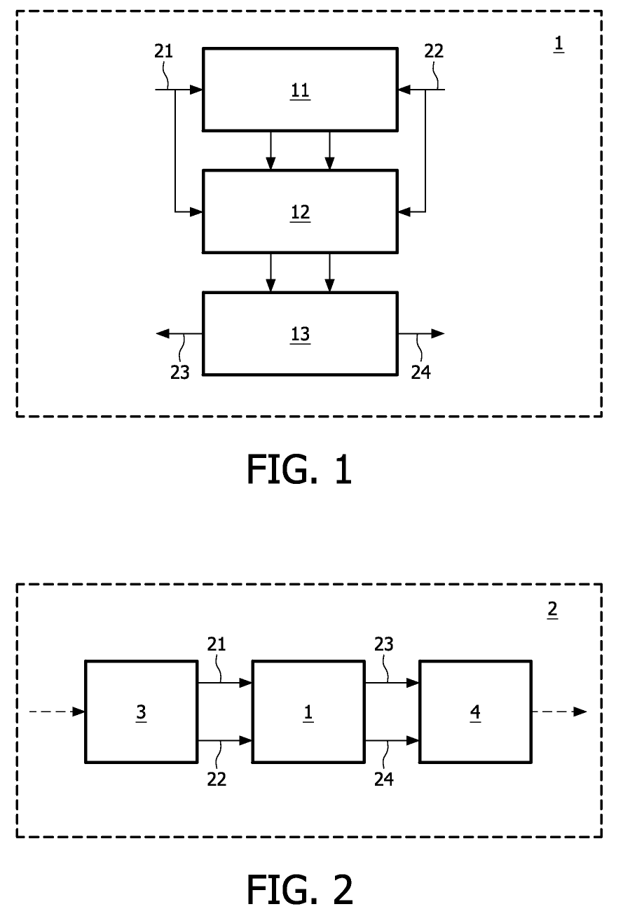

The differential amplifier 1 according to the invention shown in FIG. 1 comprises a first input stage 11 having differential inputs 21,22 for receiving a differential input signal comprising a common-mode signal and for outputting a first differential intermediate signal, a second input stage 12 for inverting the common-mode signal and for combining an inverted common-mode signal and the first differential intermediate signal into a second differential intermediate signal, and an output stage 13 for receiving the second differential intermediate signal and having differential outputs 23,24 for outputting a differential output signal.

The first input stage 11 comprises, for example, a folded cascode stage, the second input stage 12 comprises, for example, a mirror stage, and the output stage 13 comprises, for example, a common main electrode stage.

The device 2 according to the invention shown in FIG. 2 comprises a differential amplifier 1 according to the invention, an input circuit 3 coupled to the differential inputs 21,22 for supplying the differential input signal to the differential amplifier 1, and an output circuit 4 coupled to the differential outputs 23,24 for receiving the differential output signal from the differential amplifier 1. The device is, for example, a television receiver or another consumer or non-consumer product, or a circuit such as a converter and a tuner to be used in consumer and/or non-consumer products.

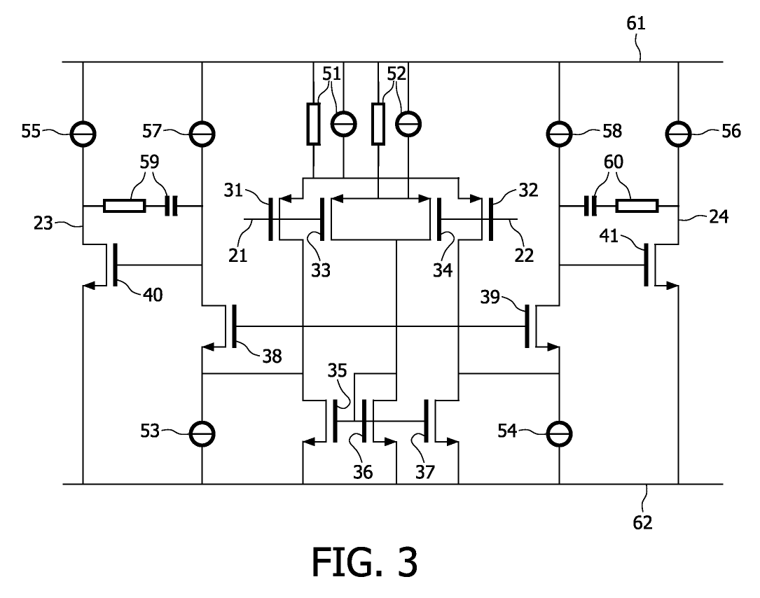

The first embodiment of the differential amplifier 1 shown in FIG. 3 comprises first and second transistors 31,32 having control electrodes (gates), which constitute the differential inputs 21,22, and first main electrodes (sources) coupled to each other. This differential amplifier 1 further comprises third and fourth transistors 33,34 having control electrodes (gates) coupled to the control electrodes of the first and second transistors 31,32, respectively, and second main electrodes (drains) coupled to each other.

The first main electrodes of the first and second transistors 31,32 are further coupled, via a first current source 51, to a first reference terminal 61 such as a positive voltage supply, and first main electrodes of the third and fourth transistors 33,34 are coupled to each other and to the first reference terminal 61 via a second current source 52.

The differential amplifier 1 further comprises fifth, sixth and seventh transistors 35,36,37 having control electrodes (gates) coupled to each other. The fifth, sixth and seventh transistors 35,36,37 further have first main electrodes (sources) coupled to each other and to a second reference terminal 62 such as ground, while second main electrodes (drains) of the fifth and seventh transistor 35,37 are coupled to second main electrodes (drains) of the first and second transistors 31,32, respectively, and a second main electrode (drain) of the sixth transistor 36 is coupled to the second main electrodes (drains) of the third and fourth transistors 33,34 and to the control electrode of the sixth transistor 36.

The differential amplifier 1 further comprises eighth and ninth transistors 38,39 having control electrodes (gates) coupled to each other and to a third reference terminal. The eighth and ninth transistors 38,39 further have first main electrodes (sources) coupled to the second electrodes of the first and second transistors 31,32, respectively.

The first main electrodes of the eighth and ninth transistors 38,39 are further coupled to the second reference terminal 62 via third and fourth current sources 53,54, respectively. The differential amplifier 1 further comprises tenth and eleventh transistors 40,41 having control electrodes (gates) coupled to the second main electrodes of the eighth and ninth transistors 38,39, respectively. The tenth and eleventh transistors 40,41 further have first main electrodes (sources) coupled to the second reference terminal 62 and second main electrodes (drains) which constitute the differential outputs 23,24 and are coupled to the first reference terminal 61 via fifth and sixth current sources 55,56, respectively. The control electrodes of the tenth and eleventh transistors 40,41 are further coupled to the first reference terminal 61 via seventh and eighth current sources 57,58, respectively, and, via circuits 59,60, to the second main electrodes of the tenth and eleventh transistors 40,41, respectively. These circuits 59,60 have serial couplings each comprising a resistor and a capacitor.

The first and second transistors 31,32 form part of the input stage 11. The third, fourth, fifth, sixth and seventh transistors 33,34,35,36,37 form part of the second input stage 12. The tenth and eleventh transistors 40,41 form part of the output stage 13. The eighth and ninth transistors 38,39 may form part of either the second input stage 12 or the output stage 13, or they may form a separate buffer stage. The control electrodes of the eighth and ninth transistors 38,39 receive a reference signal for adjusting the differential amplifier 1 from a third reference terminal.

The first and second current sources 51,52 are shown as parallel circuits of an ideal current source and a resistor. In practice, no current source is ideal. The reason that only these two current sources are shown together with their non-ideal (non-infinite) parallel resistances is that these resistances are responsible for the problems that may result from common-mode components in the differential input signals. The circuits 59,60 have a stabilizing and frequency-compensating function.

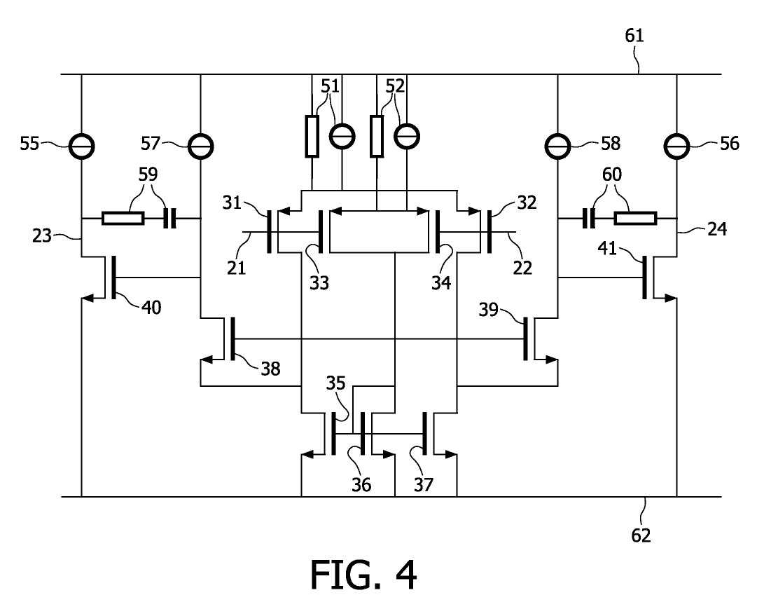

The second embodiment of the differential amplifier 1 shown in FIG. 4 corresponds to the first embodiment shown in FIG. 3, except that the third and fourth current sources 53,54 have been removed. To this end, the fifth and seventh transistors 55,57 are dimensioned in a corresponding manner.

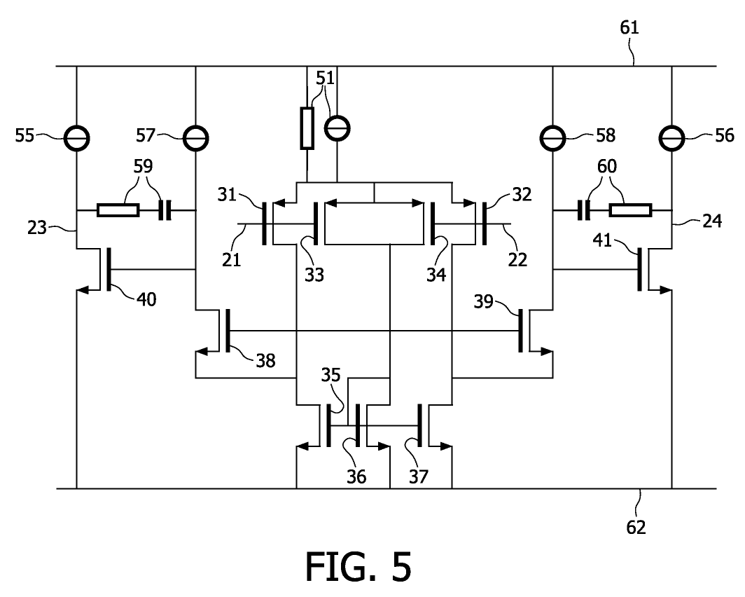

The third embodiment of the differential amplifier 1 shown in FIG. 5 corresponds to the first and second embodiments shown in FIGS. 3 and 4, except that the second current source 52 has been removed. To this end, the first current source 51 is further coupled to the first main electrodes of the third and fourth transistors 33,34 (the first main electrodes of the first and second transistors 31,32 are further coupled to the first main electrodes of the third and fourth transistors 33,34) and is dimensioned in a corresponding manner.

Instead of FET transistors, other types of transistors may be used, such as bipolar transistors, without excluding further types of transistors. The invention does not exclude feedback loops and transformers in general. The combination of signals may be an unweighted and/or a weighted combination.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. Use of the article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. A differential amplifier comprising:
a first input stage for receiving a differential input signal comprising a common-mode signal and for outputting a first differential intermediate signal,
a second input stage for inverting the common-mode signal and for combining an inverted common-mode signal and the first differential intermediate signal into a second differential intermediate signal, and
an output stage (for receiving the second differential intermediate signal and for outputting a differential output signal.

2. The differential amplifier as claimed in claim 1, wherein the first input stage comprises a folded cascode stage, the second input stage comprises a mirror stage, and the output stage comprises a common main electrode stage.

3. The differential amplifier as claimed in claim 1, wherein the first input stage comprises first and second transistors having control electrodes which constitute differential inputs, said first and second transistors further having first main electrodes coupled to each other.

4. The differential amplifier as claimed in claim 3, wherein the second input stage comprises third and fourth transistors having control electrodes coupled to the control electrodes of the first and second transistors, respectively, said third and fourth transistors further having second main electrodes coupled to each other.

5. The differential amplifier as claimed in claim 4, wherein the first main electrodes of the first and second transistors are further coupled to a first reference terminal via a first current source, and the first main electrodes of the third and fourth transistors are coupled to each other and to the first reference terminal via a second current source.

6. The differential amplifier as claimed in claim 4, wherein the first main electrodes of the first and second transistors are further coupled to first main electrodes of the third and fourth transistors as well as to a first reference terminal via a first current source.

7. The differential amplifier as claimed in claim 4, wherein the second input stage further comprises fifth, sixth and seventh transistors having control electrodes coupled to each other, said fifth, sixth and seventh transistors further having first main electrodes coupled to each other and to a second reference terminal, while second main electrodes of the fifth and seventh transistors are coupled to second main electrodes of the first and second transistors, respectively, and a second main electrode of the sixth transistor is coupled to the second main electrodes of the third and fourth transistors and to the control electrode of the sixth transistors.

8. The differential amplifier as claimed in claim 7, further comprising eighth and ninth transistors having control electrodes coupled to each other, said eighth and ninth transistors further having first main electrodes coupled to the second electrodes of the first and second transistors, respectively.

9. The differential amplifier as claimed in claim 8, wherein the first main electrodes of the eighth and ninth transistors are further coupled to the second reference terminal via third and fourth current sources, respectively.

10. The differential amplifier as claimed in claim 8, wherein the output stage comprises tenth and eleventh transistors having control electrodes coupled to the second main electrodes of the eighth and ninth transistors, respectively, said tenth and eleventh transistors further having first main electrodes coupled to the second reference terminal as well as second main electrodes which constitute differential outputs and are coupled to a first reference terminal via fifth and sixth current sources, respectively, the control electrodes of said tenth and eleventh transistors being further coupled to the first reference terminal via seventh and eighth current sources, respectively, as well as to the second main electrodes of the tenth and eleventh transistors via respective circuits, said respective circuits having serial couplings each comprising a resistor and a capacitor.

11. A device comprising a differential amplifier as claimed in claim 1.

12. A method of differentially amplifying differential signals, the method comprising the steps of:
receiving a differential input signal comprising a common-mode signal via a first input stage and outputting a first differential intermediate signal,
inverting the common-mode signal via a second input stage and combining an inverted common-mode signal and the first differential intermediate signal into a second differential intermediate signal, and
receiving the second differential intermediate signal via an output stage and outputting a differential output signal.

13. A computer program product for performing the steps of the method as claimed in claim 12.
